(19) United States
(12) Patent Application Publication
(10) Pub. No.: US 2024/0327205 A1
(43) Pub. Date: Oct. 3, 2024

(54) PRESSURE SENSING MODULE AND MANUFACTURING METHOD THEREOF

(71) Applicant: Coretronic MEMS Corporation, MIAOLI COUNTY (TW)

(72) Inventors: Mei-Ling Chen, Miaoli County (TW); Tsung-Heng Wu, Miaoli County (TW)

(73) Assignee: Coretronic MEMS Corporation, MIAOLI COUNTY (TW)

(21) Appl. No.: 18/614,740

(22) Filed: Mar. 25, 2024

(30) Foreign Application Priority Data
Mar. 28, 2023 (CN) 202310309574.6

(51) Int. Cl. B81C 1/00; B81B 3/00

(52) U.S. Cl. CPC B81C 1/00182; B81B 3/0021; B81B 2201/0264; B81B 2203/0315; B81B 2207/115; B81C 2201/0132; B81C 2201/053

(57) ABSTRACT

A pressure sensing module includes a substrate and a sensing layer. The substrate has a first surface and a second surface opposite to each other. The substrate includes a stepped cavity and an opening. The stepped cavity extends from the first surface to the second surface, the opening extends from the second surface to the first surface, and the stepped cavity communicates with the opening. The sensing layer is disposed on the first surface of the substrate and covers the first surface of the substrate. The sensing layer includes at least one sensing element and a cross-shaped structure. The cross-shaped structure includes a central portion and a plurality of extending portions connecting the central portion. The central portion and the extending portions respectively include at least one hollow portion. An orthographic projection of the central portion of the cross-shaped structure on the substrate overlaps with the opening of the substrate.

### CROSS-REFERENCE TO RELATED APPLICATION

This application claims the priority benefit of China application serial no. 202310309574.6, filed on Mar. 28, 2023. The entirety of the above-mentioned patent application is hereby incorporated by reference herein and made a part of this specification.

### BACKGROUND

### Technical Field

The present disclosure relates to a sensing module and a manufacturing method thereof, and in particular to a pressure sensing module and a manufacturing method thereof.

### Description of Related Art

A piezo-resistive microelectromechanical system (MEMs) pressure sensor is configured to convert pressure into a corresponding electronic signal. Generally, a piezo-resistive MEMS pressure sensor includes a flexible sensing film with at least one sensing element disposed in the sensing film. The sensing film may be provided to measure the applied pressure by measuring the change in resistance caused by the pressure applied to the sensing film. In the current manufacturing process of the piezo-resistive MEMS pressure sensor, the thickness of the sensing film is adjusted through backside wet etching, and the etching depth is determined depending on the time of immersing the sensing film in the liquid. However, such manufacturing method causes difficulties in controlling the thickness of the film, and therefore the manufacturing process is relatively difficult.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the disclosure was acknowledged by a person of ordinary skill in the art.

### SUMMARY

The present disclosure provides a pressure sensing module, which has improved sensitivity for sensing and is able to improve the burst pressure.

The present disclosure further provides a method for manufacturing the pressure sensing module, which is provided to manufacture the above-mentioned pressure sensing module, and has the advantages of simple manufacturing process and high yield.

Other purposes and advantages of the present disclosure can be further understood from the technical characteristics disclosed in the present disclosure.

In order to achieve one or part or all of the above purposes or other purposes, an embodiment of the present disclosure provides a pressure sensing module, which includes a substrate and a sensing layer. The substrate has a first surface and a second surface opposite to each other. The substrate includes a stepped cavity and an opening. The stepped cavity extends from the first surface to the second surface, the opening extends from the second surface to the first surface, and the stepped cavity communicates with the opening. The sensing layer is disposed on the first surface of the substrate and covers the first surface of the substrate. The sensing layer includes at least one sensing element and a cross-shaped structure. The cross-shaped structure includes a central portion and a plurality of extending portions connecting the central portion. The central portion and the extending portions respectively include at least one hollow portion. An orthographic projection of the central portion of the cross-shaped structure on the substrate overlaps with the opening of the substrate.

In order to achieve one or part of or all of the above purposes or other purposes, an embodiment of the present disclosure provides a method for manufacturing a pressure sensing module, which includes the following steps: forming a first annular cavity on a substrate to define at least one supporting structure on the substrate, and the substrate has a first surface and a second surface opposite to each other, the first annular cavity extends from the first surface to the second surface and encloses at least one supporting structure; forming a second annular cavity on the substrate, and the second annular cavity extends from the first surface to the second surface and communicates with the first annular cavity, the second annular cavity and the first annular cavity define a stepped cavity; forming a sensing layer on the substrate, and the sensing layer covers the first surface of the substrate, the sensing layer includes at least one sensing element; forming a cross-shaped structure on the sensing layer, and the cross-shaped structure includes a central portion and a plurality of extending portions connecting the central portion, the central portion and the extending portion respectively include at least one hollow portion, removing a portion of the substrate and the at least one supporting structure in a direction from the second surface to the first surface of the substrate, thereby forming an opening communicating with the stepped cavity, and an orthographic projection of the central portion of the cross-shaped structure on the substrate overlaps with the opening.

Based on the above, the embodiments of the present disclosure have at least one of the following advantages or effects. In the design of the pressure sensing module of the present disclosure, the sensing layer includes a cross-shaped structure, and the central portion and the extending portion of the cross-shaped structure respectively include at least one hollow portion. Therefore, in addition to having improved structural symmetry, the sensing layer of the present disclosure may also reduce the rigidity of the sensing layer through the hollow portion, so as to improve the sensitivity for sensing. In addition, the substrate of the present disclosure has a stepped cavity. When the sensing layer is deformed by a pressure exceeding the operating range, the sensing layer will abut against the stepped cavity thereunder. If the pressure continues to increase, the deformation area of the sensing layer will be reduced and the burst pressure will increase. Therefore, the pressure sensing module of the present disclosure has improved sensitivity for sensing and is able to improve burst pressure.

Other objectives, features and advantages of the present disclosure will be further understood from the further technological features disclosed by the embodiments of the present disclosure wherein there are shown and described preferred embodiments of this disclosure, simply by way of illustration of modes best suited to carry out the disclosure.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A to FIG. 1G are schematic cross-sectional views of a method of manufacturing a pressure sensing module according to an embodiment of the present disclosure.

FIG. 2A to FIG. 2C are schematic top views of FIG. 1A.

FIG. 2D is a schematic top view of FIG. 1F.

FIG. 3 is a schematic cross-sectional view of applying pressure to FIG. 1G.

FIG. 4A is a schematic cross-sectional view of partial steps of a method of manufacturing a pressure sensing module according to another embodiment of the present disclosure.

FIG. 4B is a schematic top view of FIG. 4A.

FIG. 5A is a schematic cross-sectional view of partial steps of a method of manufacturing a pressure sensing module according to still another embodiment of the present disclosure.

FIG. 5B is a schematic top view of FIG. 5A.

FIG. 6A to FIG. 6D are schematic cross-sectional views of partial steps of a method of manufacturing a pressure sensing module according to yet another embodiment of the present disclosure.

FIG. 6E is a schematic top view of FIG. 6D.

FIG. 7 is a schematic cross-sectional view of applying pressure to FIG. 6D.

### DESCRIPTION OF THE EMBODIMENTS

In the following detailed description of the preferred embodiments, reference is made to the accompanying drawings which form a part hereof, and in which are shown by way of illustration specific embodiments in which the disclosure may be practiced. In this regard, directional terminology, such as “top,” “bottom,” “front,” “back,” etc., is used with reference to the orientation of the Figure(s) being described. The components of the present disclosure can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present disclosure. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

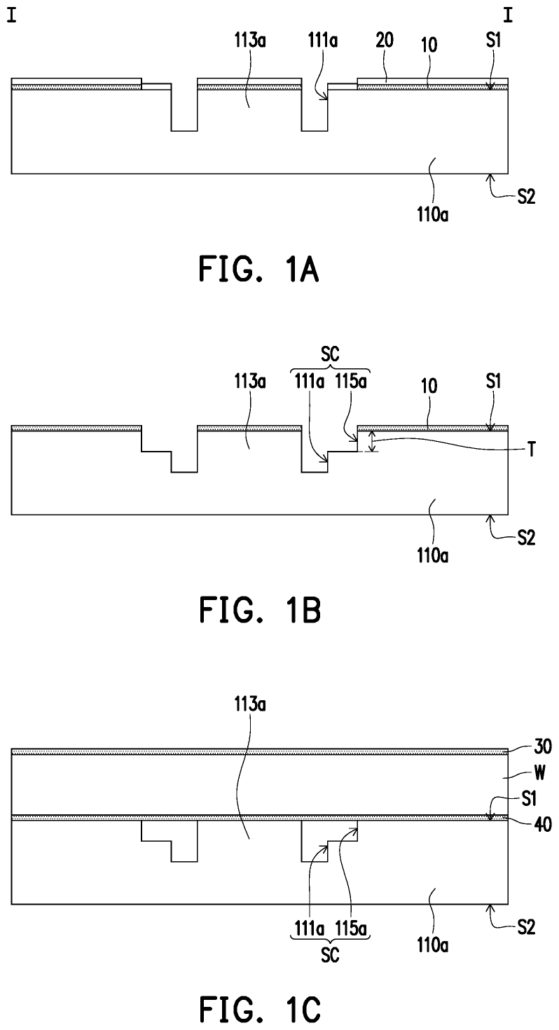

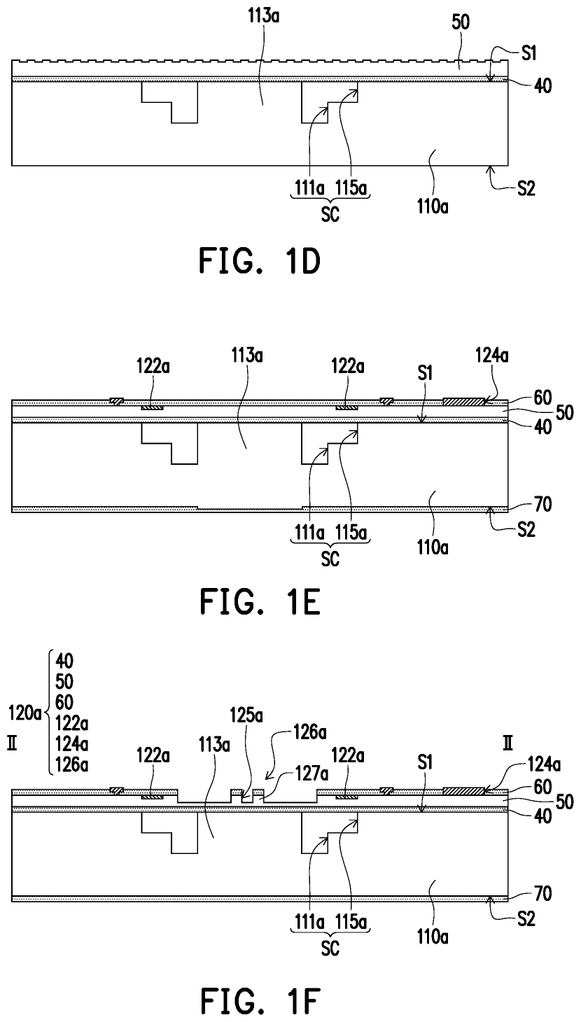

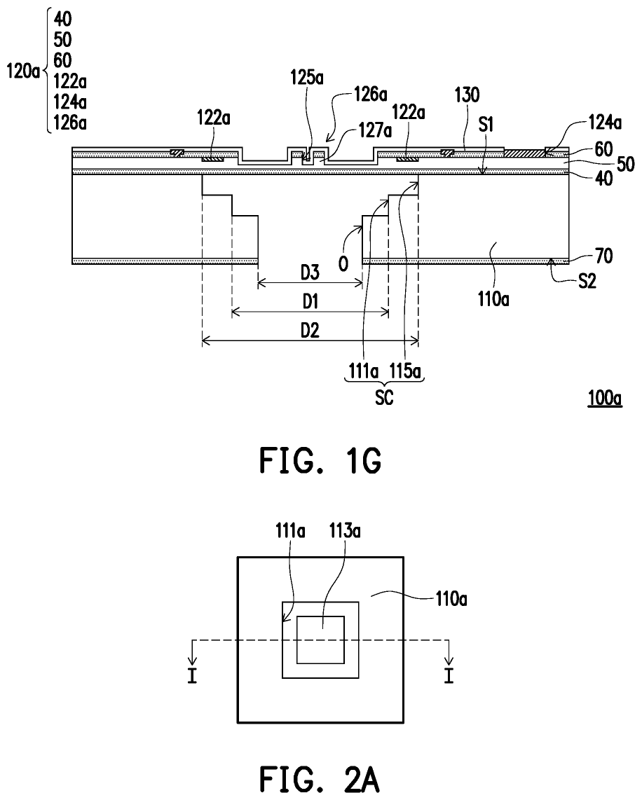

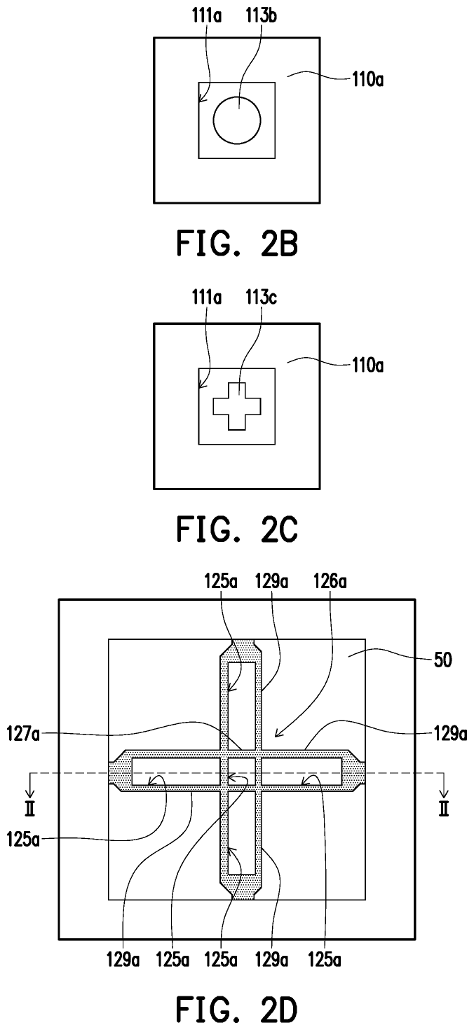

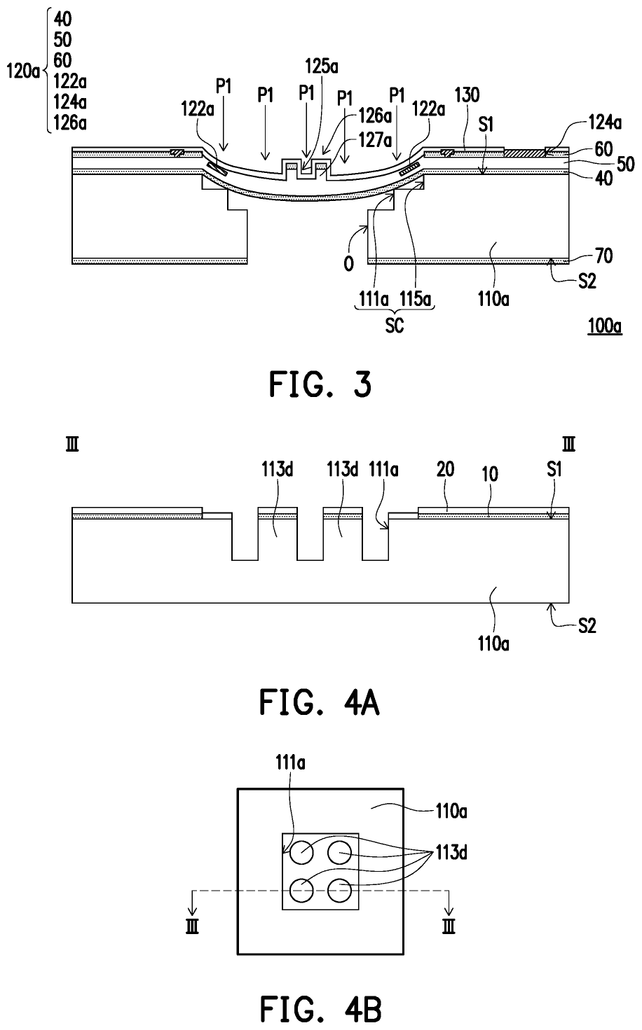

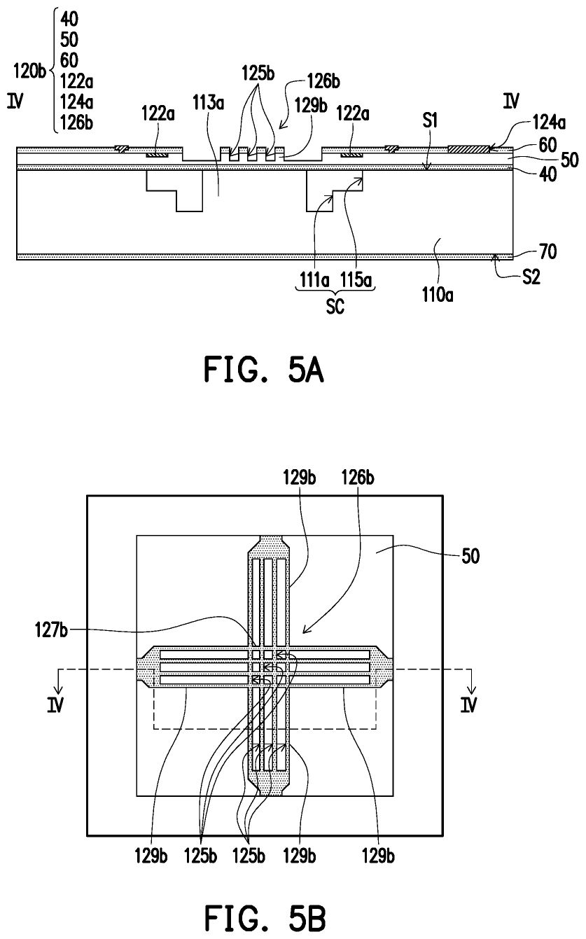

FIG. 1A to FIG. 1G are schematic cross-sectional views of a method of manufacturing a pressure sensing module according to an embodiment of the present disclosure. FIG. 2A to FIG. 2C are schematic top views of FIG. 1A. FIG. 2D is a schematic top view of FIG. 1F. FIG. 3 is a schematic cross-sectional view of applying pressure to FIG. 1G. FIG. 4A is a schematic cross-sectional view of partial steps of a method of manufacturing a pressure sensing module according to another embodiment of the present disclosure. FIG. 4B is a schematic top view of FIG. 4A. FIG. 5A is a schematic cross-sectional view of partial steps of a method of manufacturing a pressure sensing module according to still another embodiment of the present disclosure. FIG. 5B is a schematic top view of FIG. 5A.

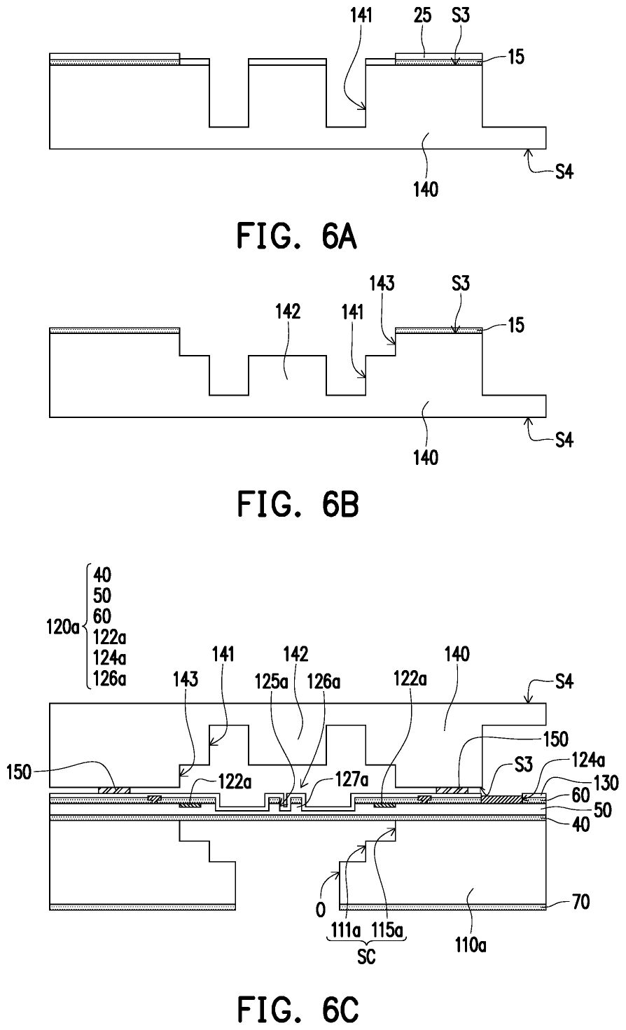

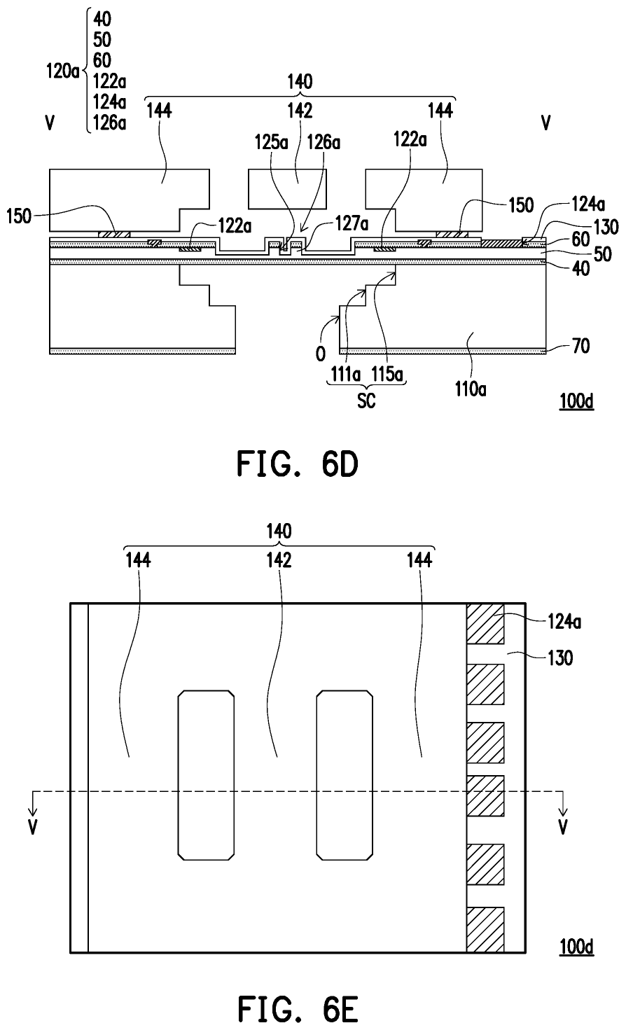

FIG. 1A is a schematic sectional view along line I-I of FIG. 2A; FIG. 1F is a schematic sectional view along line II-II of FIG. 2D; FIG. 4A is a schematic sectional view along line III-III of FIG. 4B; FIG. 5A is a schematic cross-sectional view along the line IV-IV in FIG. 5B; FIG. 6D is a schematic cross-sectional view along the line V-V in FIG. 6E. For clarity, FIG. 2A, FIG. 2B and FIG. 2C do not show the oxide layer and photoresist layer in FIG. 1A, and FIG. 4B does not show the oxide layer and photoresist layer in FIG. 4A.

Please refer to FIG. 1A and FIG. 2A both. In the manufacturing method of the pressure sensing module of this embodiment, firstly, a first annular cavity 111a is formed on the substrate 110a to define at least one supporting structure (one supporting structure 113a is schematically depicted) on the substrate 110a. The substrate 110a has a first surface S1 and a second surface S2 opposite to each other. The substrate 110a is, for example, a silicon substrate. The steps of forming the first annular cavity 111a on the substrate 110a are as follows. First, an oxide layer 10 is deposited on the first surface S1 of the substrate 110a, and the oxide layer 10 covers a portion of the first surface S1 of the substrate 110a. The oxide layer 10 is, for example, a silicon dioxide (SiO₂) layer. Next, a photoresist layer 20 is formed on the first surface S1 of the substrate 110 a, and the photoresist layer 20 covers the oxide layer 10 and a portion of the first surface S1 not covered by the oxide layer 10. Under the circumstances, the area on the first surface S1 that is not covered by the photoresist layer 20 is the area where the first annular cavity 111a is to be formed, that is, the oxide layer 10 and the photoresist layer 20 cover the rest of the first surface S1, and a portion of the photoresist layer 20 is located on the oxide layer 10. Afterwards, the photoresist layer 20 serves as a mask, the first surface S1 of the substrate 110a not covered by the photoresist layer 20 is etched to form the first annular cavity 111a. As shown in FIG. 1A, the first annular cavity 111a extends from the first surface S1 to the second surface S2 and encloses the supporting structure 113a.

As shown in FIG. 2A, the shape of the supporting structure 113a may be, for example, a rectangle. In other embodiments, please refer to FIG. 2B, the shape of the supporting structure 113b may be, for example, a circle; or, please refer to FIG. 2C, the shape of the supporting structure 113c may be, for example, a cross. The supporting structures 113a, 113b, and 113c are only schematically shown as one. In another embodiment, please refer to FIG. 4A and FIG. 4B both. The shape of the supporting structure 113d may be, for example, a circle, and there may be multiple supporting structures 113d, such as four supporting structures. The shapes of the supporting structures 113a, 113b, 113c, and 113d in this embodiment include at least one of circular, rectangular, and cross shapes. The supporting structures 113a, 113b, 113c, and 113d are provided to improve the process yield.

Next, referring to FIG. 1A and FIG. 1B, the photoresist layer 20 is removed to expose the oxide layer 10 and a portion of the first surface S1 of the substrate 110a not covered by the oxide layer 10. Under the circumstances, an area of the first surface S1 not covered by the oxide layer 10 is the area where the second annular cavity 115a is to be formed. Afterwards, a dry etching process is performed on the first surface S1 of the substrate 110a to form a second annular cavity 115a on the substrate 110a. The second annular cavity 115a extends from the first surface S1 to the second surface S2 and communicates with the first annular cavity 111a. The second annular cavity 115a and the first annular cavity 111a define a stepped cavity SC. In an embodiment, the depth T of the second annular cavity 115a may be, for example, 3 microns.

Next, please refer to FIG. 1B, FIG. 1F and FIG. 1C at the same time. The oxide layer 10 is removed, and the sensing layer 120a is formed on the substrate 110a. The steps of forming the sensing layer 120a on the substrate 110a are as follows. First, please refer to FIG. 1C, which shows bonding the wafer W and disposing the first oxide layer 30 and the second oxide layer 40 on the substrate 110a, the first oxide layer 30 and the second oxide layer 40 are located on opposite sides of the wafer W, and the second oxide layer 40 directly contacts the first surface S1 of the substrate 110a. The first oxide layer 30 and the second oxide layer 40 may be, for example, silicon dioxide (SiO₂) layers, respectively. The wafer W is, for example, a silicon wafer. At this point, a semiconductor-on-insulator (SOI) substrate has been formed.

Next, referring to FIG. 1C and FIG. 1D simultaneously, the first oxide layer 30 and a portion of the wafer W are removed to form the active layer 50. Here, the method of removing the first oxide layer 30 and a portion of the wafer W is, for example, grinding.

Next, referring to FIG. 1E, at least one sensing element (two sensing elements 122a are schematically shown) is formed in the active layer 50. Here, the sensing element 122a is, for example, a piezo-resistive sensor. Next, the third oxide layer 60 is disposed on the active layer 50 and the sensing element 122a, and the fourth oxide layer 70 is disposed on the second surface S2 of the substrate 110a. The third oxide layer 60 and the fourth oxide layer 70 may be, for example, silicon dioxide (SiO₂) layers, respectively. Then, a patterned metal layer 124a is formed on the third oxide layer 60, and a portion of the patterned metal layer 124a may directly contact the active layer 50 and extend to the third oxide layer 60. Here, the material of the patterned metal layer 124a is, for example, aluminum copper (AlCu), but the disclosure is not limited thereto.

Thereafter, please refer to FIG. 1F and FIG. 2D both, which show forming at least one hollow portion (a plurality of hollow parts 125a are schematically depicted) to penetrate through the third oxide layer 60 and a portion of the active layer 50, thus defining a cross-shaped structure 126a. Here, the method of forming the hollow portion 125a is, for example, performing dry etching or front wet etching in a direction from the first surface S1 to the second surface S2 of the substrate 110a. At this stage, the cross-shaped structure 126a has been formed on the sensing layer 120a, and the fabrication of the sensing layer 120a is completed. In short, in this embodiment, the sensing layer 120a is formed by grinding and dry etching or front wet etching. As compared with related art which forms the sensing film by backside wet etching, the present embodiment is able to effectively control the thickness, thereby improving the process yield and the sensitivity of the sensing layer 120a for sensing.

As shown in FIG. 1F and FIG. 2D, the sensing layer 120a of this embodiment covers the first surface S1 of the substrate 110a, and the sensing layer 120a includes a sensing element 122a, a patterned metal layer 124a, a cross-shaped structure 126a, the second oxide layer 40, the active layer 50 and the third oxide layer 60. The cross-shaped structure 126a includes a central portion 127a and a plurality of extending portions (four extending portions 129a are schematically shown) connecting the central portion 127a, and the central portion 127a and the extending portions 129a respectively include a hollow portion 125a. Here, the cross-shaped structure 126a is, for example, in the shape of double ribs.

In another embodiment, please refer to FIG. 5A and FIG. 5B at the same time, the cross-shaped structure 126b of the sensing layer 120b includes a central portion 127b and a plurality of extending portions (four extending portions 129b are schematically shown) connecting the central portion 127b, and the central portion 127b and the extending portions 129b respectively include a plurality of hollow portions 125b. In an embodiment, the central portion 127b may include, for example, nine hollow portions 125b, and each extending portion 129b may, for example, include three hollow portions 125b. Here, the cross-shaped structure 126b may be, for example, in the shape of a grid.

The setting of the hollow portions 125a and 125b is to form hollow double-rib or grid-like cross-shaped structures 126a and 126b, and the number of rib-like/grid-like structures of the cross-shaped structures 126a and 126b may be N, and N is limited by the relationship between manufacturing capability and film size. Taking FIG. 2D as an example, the number N of rib-like structure of the double-rib cross-shaped structure 126a is two. Taking FIG. 5B as an example, the number N of grid-like structure of the grid-shaped cross-shaped structure 126b is four. The width of each rib-like/grid-like structure is reduced through the design of the hollowed portions 125a and 125b, and the distance between the rib-like/grid-like structure is increased, thus reducing the rigidity and elastic coefficient of the sensing layers 120a and 120b while improving sensitivity. The toughness of the sensing layers 120a and 120b may be enhanced through the connection between the multiple rib-like/grid-like structures, thereby improving the process variation tolerance and safety factor, and realizing a higher burst pressure.

Next, referring to FIG. 1G, a protective layer 130 is formed on the sensing layer 120a to cover the sensing element 122a, the patterned metal layer 124a and the cross-shaped structure 126a. Here, the protective layer 130 exposes a portion of the patterned metal layer 124a, and the material of the protective layer 130 is, for example, silicon nitride (Si₃N₄). Finally, please refer to FIG. 1F and FIG. 1G at the same time, a portion of the fourth oxide layer 70, a portion of the substrate 110a and the supporting structure 113a are removed in a direction from the second surface S2 to the first surface S1 of the substrate 110a to form an opening O communicating with the stepped cavity SC. The orthographic projection of the central portion 127a of the cross-shaped structure 126a on the substrate 110a overlaps with the opening O. At this stage, the fabrication of the pressure sensing module 100a has been completed, and the substrate 110a has been formed into a cavity-semiconductor-on-insulator (C-SOI) substrate.

Please refer to FIG. 1G and FIG. 2D at the same time. Structurally, the pressure sensing module 100a includes the substrate 110a and the sensing layer 120a. The substrate 110a has the first surface S1 and the second surface S2 opposite to each other. The substrate 110a includes the stepped cavity SC and an opening O. The stepped cavity SC extends from the first surface S1 to the second surface S2, the opening O extends from the second surface S2 to the first surface S1, and the stepped cavity SC communicates with the opening O. Here, the stepped cavity SC includes a first annular cavity 111a and a second annular cavity 115a. The first annular cavity 111a is located between the opening O and the second annular cavity 115a. The diameter D1 of the first annular cavity 111a is smaller than the diameter D2 of the second annular cavity 115a and larger than the diameter D3 of the opening O.

The sensing layer 120a of this embodiment is disposed on the first surface S1 of the substrate 110a and covers the first surface S1 of the substrate 110a. The sensing layer 120a includes a sensing element 122a and a cross-shaped structure 126a. The cross-shaped structure 126a includes a central portion 127a and a plurality of extending portions 129a connecting the central portion 127a, and the central portion 127a and the extending portions 129a respectively include at least one hollow portion 125a. The orthographic projection of the central portion 127a of the cross-shaped structure 126a on the substrate 110a overlaps with the opening O of the substrate 110a. Here, the cross-shaped structure 126a may be in the shape of double ribs or a grid.

In this embodiment, the sensing layer 120a further includes an oxide layer 60 (i.e., the third oxide layer), an oxide layer 40 (i.e., the second oxide layer), an active layer 50, and a patterned metal layer 124a. The active layer 50 is located between the oxide layer 60 and the oxide layer 40. The oxide layer 40 is disposed on the first surface S1 of the substrate 110a. The sensing element 122a is embedded in the active layer 50. The hollow portion 125a penetrates through the oxide layer 60 and a portion of the active layer 50. The patterned metal layer 124a is disposed on at least one of the oxide layer 60 and the active layer 50.

The pressure sensing module 100a of this embodiment further includes the protective layer 130 disposed on the sensing layer 120a to cover the sensing element 122a and the cross-shaped structure 126a. Here, the material of the protective layer 130 is, for example, silicon nitride (Si₃N₄).

Please refer to FIG. 3, when the pressure P1 is applied on the pressure sensing module 100a, the stepped cavity SC may support the deformed sensing layer 120a to limit the deformation space of the sensing layer 120a. If the pressure P1 continues to increase, the deformation area of the sensing layer 120a will be reduced, and the maximum stress of the sensing layer 120a will decrease, so the maximum pressure that the sensing layer 120a can withstand increases accordingly, that is, the burst pressure increases.

In short, since the sensing layer 120a of this embodiment is designed with the cross-shaped structure 126a, and the central portion 127a and the extending portion 129a of the cross-shaped structure 126a respectively include the hollow portion 125a, in addition to having improved structural symmetry, the sensing layer 120a of this embodiment may also reduce the rigidity of the sensing layer 120a through the hollow portion 125a, so as to improve the sensitivity for sensing. The substrate 110a of this embodiment is designed with the stepped cavity SC. When the sensing layer 120a is deformed by a pressure exceeding the operating range, the sensing layer 120a will abut against the stepped cavity SC thereunder. If the pressure increases continuously, the deformation area of the sensing layer 120a will be reduced and the burst pressure will increase. Therefore, the pressure sensing module 100a of this embodiment has improved sensitivity for sensing and improved burst pressure. Moreover, since the sensing layer 120a of this embodiment is not formed by backside wet etching, but by grinding and dry etching or front wet etching, the thickness of the sensing layer 120a may be controlled easily, and the process yield is high.

That the following embodiments continue to adopt the component numbers and part of the content of the previous embodiments, and the same numbers are used to indicate the same or similar components, and the description of the same technical content is omitted. For the description of omitted parts, reference may be made to the foregoing embodiments, and the related details will not be repeated.

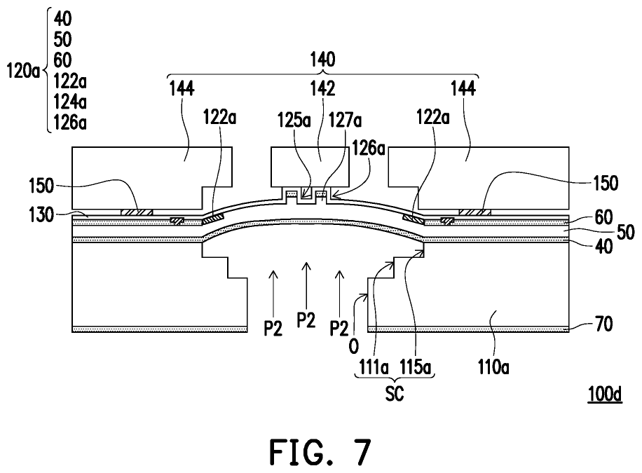

FIG. 6A to FIG. 6D are schematic cross-sectional views of partial steps of a method of manufacturing a pressure sensing module according to yet another embodiment of the present disclosure. FIG. 6E is a schematic top view of FIG. 6D. FIG. 7 is a schematic cross-sectional view of applying pressure to FIG. 6D. FIG. 6D is a schematic cross-sectional view along line V-V of FIG. 6E.

The manufacturing method of the pressure sensing module 100d of this embodiment is similar to the manufacturing method of the pressure sensing module 100a described above. The difference between the two is: following the step in FIG. 1G, please refer to FIG. 6D, which shows bonding a cover 140 to the protective layer 130. First, referring to FIG. 6A, the cover 140 is provided, and the cover 140 has a third surface S3 and a fourth surface S4 opposite to each other. Next, an oxide layer 15 is deposited on the third surface S3 of the cover 140, the oxide layer 15 covers a portion of the third surface S3 of the cover 140. The oxide layer 15 is, for example, a silicon dioxide (SiO₂) layer. Then, a photoresist layer 25 is formed on the third surface S3 of the cover 140, and the photoresist layer 25 covers the oxide layer 15 and a portion of the third surface S3 not covered by the oxide layer 15. Under the circumstances, an area on the third surface S3 not covered by the photoresist layer 25 is the area where the third cavity 141 is to be formed, that is, the oxide layer 15 and the photoresist layer 25 cover the rest of the third surface S3, and a portion of the photoresist layer 25 is located on the oxide layer 15. Afterwards, the photoresist layer 25 is used as a mask, the third surface S3 of the cover 140 not covered by the photoresist layer 25 is etched to form the third cavity 141. Here, the third cavity 141 has been formed on the cover 140, and the third cavity 141 extends from the third surface S3 to the fourth surface S4.

Next, please refer to FIG. 6A and FIG. 6B at the same time, the photoresist layer 25 is removed to expose the oxide layer 15 and a portion of the third surface S3 of the cover 140 not covered by the oxide layer 15. At this point, the area on the third surface S3 not covered by the oxide layer 15 is the area where the fourth cavity 143 is to be formed. Afterwards, a dry etching process is performed on the third surface S3 of the cover 140 to form the fourth cavity 143 on the cover 140, and the fourth cavity 143 extends from the third surface S3 to the fourth surface S4 and communicates with the third cavity 141 to define a first portion 142.

Next, referring to FIG. 6C, the cover 140 is bonded to the protective layer 130 through a bonding substance 150, and the third surface S3 of the cover 140 directly contacts the bonding substance 150 and the protective layer 130. Here, the bonding substance 150 is, for example, a dry film.

Thereafter, please refer to FIG. 6C, FIG. 6D and FIG. 6E at the same time, a portion of the cover 140 is removed in a direction from the fourth surface S4 to the third surface S3 of the cover 140 to define the second portion 144 of the cover 140, and the second portion 144 encloses the first portion 142. Here, the method of removing a portion of the cover 140 is, for example, grinding. Here, the cover 140 has been bonded to the protective layer 130, and the cover 140 includes a first portion 142 and a second portion 144 enclosing the first portion 142. The first portion 142 corresponds to at least a portion of the cross-shaped structure 126a, and the second portion 144 is bonded to the protective layer 130. The first portion 142 corresponds to the central portion 127a of the cross-shaped structure 126a. At this stage, the fabrication of the pressure sensing module 100d has been completed. Here, the material of the cover 140 is the same as that of the substrate 110a, that is, the material of the cover 140 is cavity-semiconductor-on-insulator (C-SOI).

Please refer to FIG. 7, when the pressure P2 is applied on the pressure sensing module 100d, the deformed sensing layer 120a will first abut against the cover 140 located above, and the cover 140 may limit the maximum deformation of the sensing layer 120a, and is able to improve the burst pressure. In short, the pressure sensing module 100d of this embodiment is able to support the sensing layer 120a deformed downwardly through the design of the substrate 110a having the stepped cavity SC, and through the setting of the cover 140, it is possible to support the sensing layer 120a deformed upwardly.

In a simulation experiment, the simulation comparison was carried out by comparing a pressure sensing module with a solid cross-shaped structure (that is, without a hollow portion) in the related art with the pressure sensing module 100a having a double-rib or grid-shaped cross-shaped structure 126a/126b of this embodiment.

TABLE 1

| | Pressure sensing module | | Pressure sensing module | |
|---|---|---|---|---|
| | with a solid cross- | | 100a having a double-rib | |
| | shaped structure in the | | or grid-shaped cross- | |
| | related art | | shaped structure 126a/126b | |
| Size of cavity | 1200 | microns | 1200 | microns |
| Size of rib/grid | 60 microns to 80 | | 3 microns to 20 | |
| | microns | | microns | |
| Number of ribs/ | Single | | Plural | |
| grid | | | | |
| Output sensitivity | 100% | | 115% | |
| (mV/V/kPa) | | | | |
| Film deformation | 1420 | MPa | 1410 | MPa |
| stress (1 ATM) | | | | |
| Amount of film | 35.8 | microns | 37.9 | microns |
| deformation (1 | | | | |
| ATM) | | | | |

As shown in Table 1 above, the sensitivity of the pressure sensing module 100a with the cross-shaped structure 126a/126b having the double-rib shape or a grid shape (that is, the hollow portion 125a/125b is provided) may be increased by 15%, while the amount of film deformation is also increased, which in turn is able to increase the burst pressure.

Based on the above, the embodiments of the present disclosure have at least one of the following advantages or effects. In the design of the pressure sensing module of the present disclosure, the sensing layer includes a cross-shaped structure, and the central portion and the extending portion of the cross-shaped structure respectively include at least one hollow portion. Therefore, in addition to having improved structural symmetry, the sensing layer of the present disclosure may also reduce the rigidity of the sensing layer through the hollow portion, so as to improve the sensitivity for sensing. In addition, the substrate of the present disclosure has a stepped cavity. When the sensing layer is deformed by a pressure exceeding the operating range, the sensing layer will abut against the stepped cavity thereunder. If the pressure continues to increase, the deformation area of the sensing layer will be reduced and the burst pressure will increase. Therefore, the pressure sensing module of the present disclosure has improved sensitivity for sensing and is able to improve burst pressure.

The foregoing description of the preferred embodiments of the disclosure has been presented for purposes of illustration and description. It is not intended to be exhaustive or to limit the disclosure to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the disclosure and its best mode practical application, thereby to enable persons skilled in the art to understand the disclosure for various embodiments and with various modifications as are suited to the particular use or implementation contemplated. It is intended that the scope of the disclosure be defined by the claims appended hereto and their equivalents in which all terms are meant in their broadest reasonable sense unless otherwise indicated. Therefore, the term “the disclosure”, “the present disclosure” or the like does not necessarily limit the claim scope to a specific embodiment, and the reference to particularly preferred exemplary embodiments of the disclosure does not imply a limitation on the disclosure, and no such limitation is to be inferred. The disclosure is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the disclosure. It should be appreciated that variations may be made in the embodiments described by persons skilled in the art without departing from the scope of the present disclosure as defined by the following claims. Moreover, no element and component in the present disclosure is intended to be dedicated to the public regardless of whether the element or component is explicitly recited in the following claims.

What is claimed is:

1. A pressure sensing module, comprising:
a substrate, having a first surface and a second surface opposite to each other, wherein the substrate comprises a stepped cavity and an opening, the stepped cavity extends from the first surface to the second surface, the opening extends from the second surface to the first surface, and the stepped cavity communicates with the opening; and
a sensing layer, disposed on the first surface of the substrate and covering the first surface of the substrate, wherein the sensing layer comprises:
at least one sensing element; and
a cross-shaped structure, comprising a central portion and a plurality of extending portions connecting the central portion, wherein the central portion and the extending portions respectively comprise at least one hollow portion, and an orthographic projection of the central portion of the cross-shaped structure on the substrate overlaps with the opening of the substrate.

2. The pressure sensing module according to claim 1, wherein the stepped cavity comprises a first annular cavity and a second annular cavity, the first annular cavity is located between the opening and the second annular cavity, a diameter of the first annular cavity is smaller than a diameter of the second annular cavity and larger than a diameter of the opening.

3. The pressure sensing module according to claim 1, further comprising:
a protective layer, disposed on the sensing layer to cover the at least one sensing element and the cross-shaped structure.

4. The pressure sensing module according claim 3, wherein a material of the protective layer comprises silicon nitride.

5. The pressure sensing module according to claim 3, further comprising:
a cover, disposed on the protective layer, wherein the cover comprises a first portion and a second portion enclosing the first portion, the first portion corresponds to at least a portion of the cross-shaped structure, and the second portion is bonded to the protective layer.

6. The pressure sensing module according to claim 5, wherein a material of the cover is the same as that of the substrate.

7. The pressure sensing module according to claim 1, wherein the substrate is a cavity-semiconductor-on-insulator (C-SOI) substrate.

8. The pressure sensing module according to claim 1, wherein the sensing layer further comprises a first oxide layer, a second oxide layer, an active layer and a patterned metal layer, the active layer is located between the first oxide layer and the second oxide layer, the second oxide layer is configured on the first surface of the substrate, the at least one sensing element is embedded in the active layer, the at least one hollow portion penetrates through the first oxide layer and a portion of the active layer, the patterned metal layer is disposed on at least one of the first oxide layer and the active layer.

9. The pressure sensing module according to claim 1, wherein the cross-shaped structure is double-rib or grid-shaped.

10. The pressure sensing module according to claim 1, wherein the at least one sensing element comprises at least one piezo-resistive sensor.

11. A method for manufacturing a pressure sensing module, comprising:
forming a first annular cavity on a substrate to define at least one supporting structure on the substrate, wherein the substrate has a first surface and a second surface opposite to each other, the first annular cavity extends from the first surface to the second surface and encloses the at least one supporting structure;
forming a second annular cavity on the substrate, wherein the second annular cavity extends from the first surface to the second surface and communicates with the first annular cavity, the second annular cavity and the first annular cavity define a stepped cavity;
forming a sensing layer on the substrate, wherein the sensing layer covers the first surface of the substrate, and the sensing layer comprises at least one sensing element;
forming a cross-shaped structure on the sensing layer, wherein the cross-shaped structure comprises a central portion and a plurality of extending portions connecting the central portion, the central portion and the extending portion respectively comprise at least one hollow portion; and
removing a portion of the substrate and the at least one supporting structure in a direction from the second surface to the first surface of the substrate, thereby forming an opening communicating with the stepped cavity, wherein an orthographic projection of the central portion of the cross-shaped structure on the substrate overlaps with the opening.

12. The method for manufacturing the pressure sensing module according to claim 11, further comprising:
forming a protective layer on the sensing layer to cover the at least one sensing element and the cross-shaped structure.

13. The method for manufacturing the pressure sensing module according to claim 12, further comprising:
bonding a cover to the protective layer, wherein the cover comprises a first portion and a second portion enclosing the first portion, the first portion corresponds to at least a portion of the cross-shaped structure, and the second portion is bonded to the protective layer.

14. The method for manufacturing the pressure sensing module according to claim 13, further comprising:
forming a third cavity on the cover, wherein the third cavity extends from a third surface to a fourth surface;
forming a fourth cavity on the cover, wherein the fourth cavity extends from the third surface to the fourth surface and communicates with the third cavity to define the first portion; and
after bonding the second portion of the cover to the protective layer, removing a portion of the cover in a direction from the fourth surface to the third surface of the cover.

15. The method for manufacturing the pressure sensing module according to claim 11, wherein the step of forming the first annular cavity on the substrate comprises:
depositing an oxide layer on the first surface of the substrate, wherein the oxide layer covers a portion of the first surface of the substrate;
forming a photoresist layer on the first surface of the substrate, wherein the photoresist layer covers the oxide layer and a portion of the first surface not covered by the oxide layer; and
using the photoresist layer as a mask, and etching the first surface of the substrate not covered by the photoresist layer to form the first annular cavity.

16. The method for manufacturing the pressure sensing module according to claim 15, wherein the step of forming the second annular cavity on the substrate comprises:
removing the photoresist layer to expose the oxide layer and the portion of the first surface of the substrate not covered by the oxide layer; and
performing a dry etching process on the first surface of the substrate to form the second annular cavity.

17. The method for manufacturing the pressure sensing module according to claim 11, wherein the step of forming the sensing layer on the substrate comprises:
bonding a wafer and disposing a first oxide layer and a second oxide layer on the substrate, wherein the first oxide layer and the second oxide layer are located on opposite sides of the wafer;
removing the first oxide layer and a portion of the wafer to form an active layer;
forming the at least one sensing element in the active layer;
disposing a third oxide layer on the active layer and the at least one sensing element;
forming a patterned metal layer on the third oxide layer; and
forming the at least one hollow portion to penetrate through the third oxide layer and a portion of the active layer to define the cross-shaped structure.

18. The method for manufacturing the pressure sensing module according to claim 11, wherein the method for forming the at least one hollow portion comprises a dry etching method or a front wet etching method.

19. The method for manufacturing the pressure sensing module according to claim 11, wherein a shape of the at least one supporting structure comprises at least one of a circle, a rectangle and a cross.
